(19) United States
(12) Patent Application Publication
(10) Pub. No.: US 2025/0201705 A1
(43) Pub. Date: Jun. 19, 2025

(54) SEMICONDUCTOR STRUCTURE AND METHOD FOR FABRICATING THE SAME

(71) Applicant: United Microelectronics Corp., Hsinchu (TW)

(72) Inventors: Chia-Min HUNG, Tainan City (TW); Ping-Chia SHIH, Tainan City (TW); Che-Hao KUO, Tainan City (TW); Wan-Chun LIAO, Hsinchu County (TW)

(21) Appl. No.: 18/406,251

(22) Filed: Jan. 8, 2024

(30) Foreign Application Priority Data
Dec. 13, 2023 (TW) 112148604

(51) Int. Cl. H01L 23/525; H01L 21/762; H01L 23/528; H01L 23/532

(52) U.S. Cl. CPC H01L 23/5252; H01L 21/76232; H01L 23/5283; H01L 23/53271

(57) ABSTRACT

An anti-fuse structure includes a substrate, a shallow trench isolation (STI) area, a first dielectric layer, a poly-silicon layer, a second dielectric layer and a conductive layer. The substrate has a substrate surface. The STI area extends downwardly through the substrate surface into the substrate, and the STI area has a top surface and recess extending downward from the top surface. The first dielectric layer is disposed above the STI area and covers the top surface and a corner that is formed by a vertical sidewall of the recess and the top surface. The poly-silicon layer is disposed above the first dielectric layer and covers the corner. The second dielectric layer is disposed above the poly-silicon layer and covers the corner. The conductive layer is disposed above the second dielectric layer and covers the corner.

This application claims the benefit of Taiwan Application Ser. No. 112148604 filed at Dec. 13, 2023, the subject matter of which is incorporated herein by reference.

### BACKGROUND

### Technical Field

The disclosure relates to a semiconductor device structure and a method for fabricating the same, and more particularly to an anti-fuse structure and a method for fabricating the same.

### Description of Background

The manufacturing of integrated circuits (ICs) includes forming millions of electronic devices on a single wafer or chip. During the manufacturing process, when certain electronic device failures that may cause the IC failure are detected, the subsequent manufacturing process may be stopped, the wafers in production may be discarded due to these failures, and it will lead to a waste and a significant increase on manufacturing cost. Currently, a fuse/anti-fuse fault tolerance design is provided, by which fuses/anti-fuses are widely arranged in ICs. By blowing fuses arranged in an IC to break a conductive circuit path or by blowing anti-fuses to turn an originally non-conductive circuit path into a short circuit, thereby the circuit paths of the IC can be rearranged to eliminate the failure electronic devices and to maintain the operating function of the IC without discarding the entire wafer or the chip with the failure devices.

Taking a typical anti-fuse structure consisting of an insulating layer (pattern) separating two conductor layers (patterns) as an example, the forming of a prior art anti-fuse structure, requires a plurality of photolithography etching processes to form the pattered insulating layers and these two conductor layers, and this may cost additional reticles. The processing steps and the masks used for manufacturing the IC having the prior art anti-fuse structure may be significantly increased, and the layout area and thickness of the IC may be also increased, which is not conducive to the miniaturization of the IC.

Therefore, there is a need of providing an anti-fuse structure and a method for fabricating the same to obviate the drawbacks encountered from the prior art.

### SUMMARY

One aspect of the present disclosure is to provide an anti-fuse structure, wherein the anti-fuse structure includes a substrate, a shallow trench isolation (STI) area, a first dielectric layer, a poly-silicon layer, a second dielectric layer and a conductive layer. The substrate has a substrate surface. The STI area passes through the substrate surface and extends downward into the substrate, and the STI area has a top surface and recess extending downward from the top surface. The first dielectric layer is disposed above the STI area and covers the top surface and a corner that is formed by a vertical sidewall of the recess and the top surface. The poly-silicon layer is disposed above the first dielectric layer and covers the corner. The second dielectric layer is disposed above the poly-silicon layer and covers the corner. The conductive layer is disposed above the second dielectric layer and covers the corner.

Another aspect of the present disclosure is to provide a method for fabricating an anti-fuse structure, wherein the method includes steps as follows: Firstly, a substrate is provided, and at least one STI area is formed in the substrate, passing through a surface of the substrate and extending downward into the substrate. The STI area is then etched to form a recess extending downward from a top surface of the STI area. After that, a first dielectric layer is formed above the STI area to cover the top surface and a corner that is formed by a vertical sidewall of the recess and the top surface; and then a poly-silicon layer is formed above the first dielectric layer to cover the corner. Next, a second dielectric layer is formed above the poly-silicon layer to cover the corner. A conductive layer is formed above the second dielectric layer to cover the corner.

According to the above embodiments of the disclosure, an anti-fuse structure and a method for fabricating the same are provided using existing reticles and processing steps used for manufacturing other semiconductor devices in the semiconductor manufacturing process. Firstly, an etching process is performed to form a recess concaved from the top surface of a STI area, and then a first dielectric layer, a poly-silicon layer, a second dielectric layer (for example, an interlayer dielectric layer (ILD)) and a conductive layer (such as, a metal wire layer) are formed in series to cover the corner that is formed by a vertical sidewall of the recess and the top surface of the STI area. Such that, a first distance between the portions of the poly-silicon layer corresponding to the corner and the conductive layer is lower than a second distance between the other portion of the poly-silicon layer away from the corner and the conductive layer. Thereby, an anti-fuse structure can be formed above the corner to provide an anti-fuse fault-tolerant design during the process for forming an IC, without (or not significantly) increasing the number of reticles and process steps.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1 is a flow chart illustrating a method for fabricating an anti-fuse structure according to one embodiment of the present disclosure; and

FIGS. 2A to 2G are cross-sectional views illustrating a series of the processing structures fabricating an anti-fuse structure according to one embodiment of the present disclosure.

### DETAILED DESCRIPTION

The embodiments as illustrated below provide an anti-fuse structure and a method for fabricating the same, which can provide an anti-fuse fault-tolerant design during the process for forming an IC, without (or not significantly) increasing the number of reticles and process steps. The present disclosure will now be described more specifically with reference to the following embodiments illustrating the structure, method and arrangements thereof.

It is to be noted that the following descriptions of preferred embodiments of this disclosure are presented herein for purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

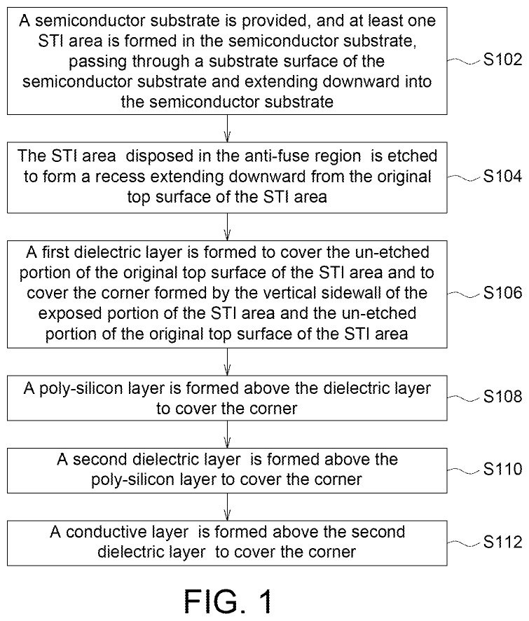

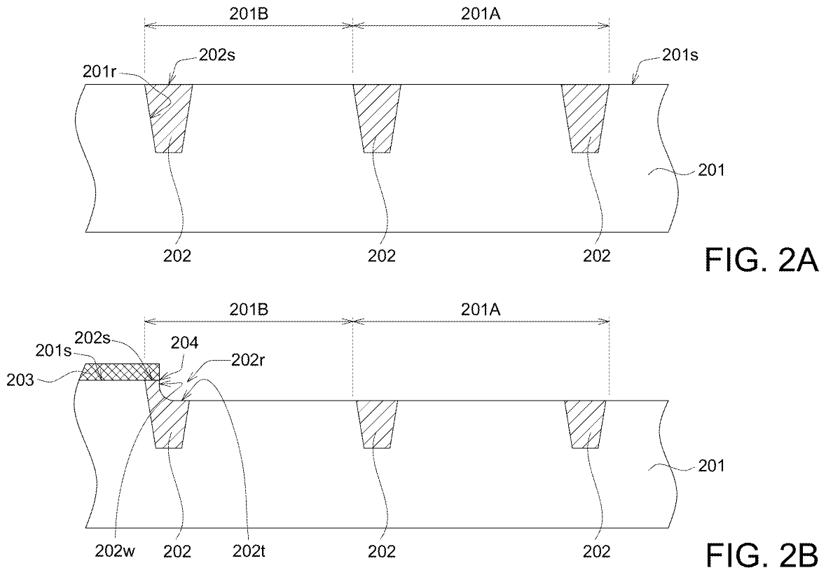

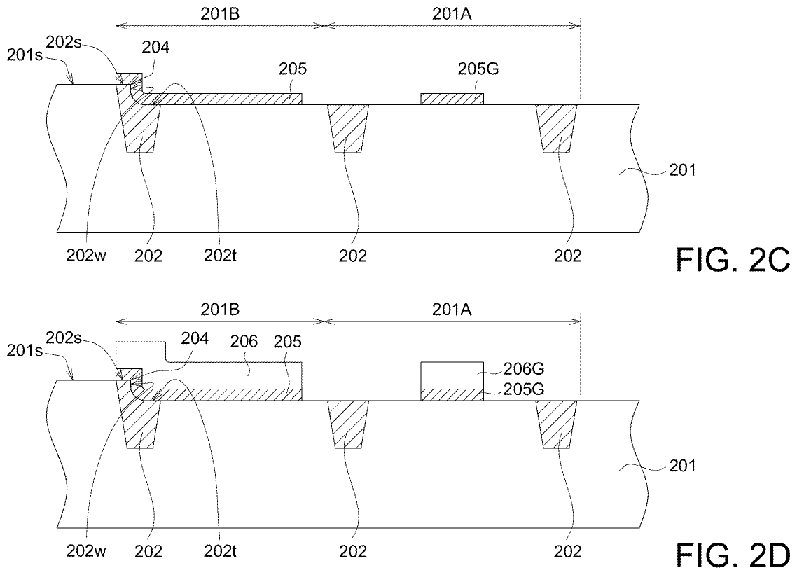

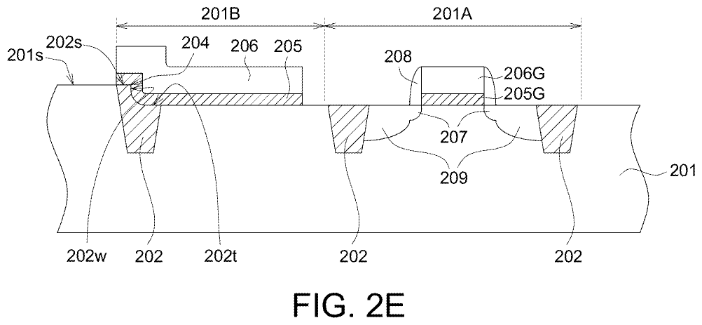

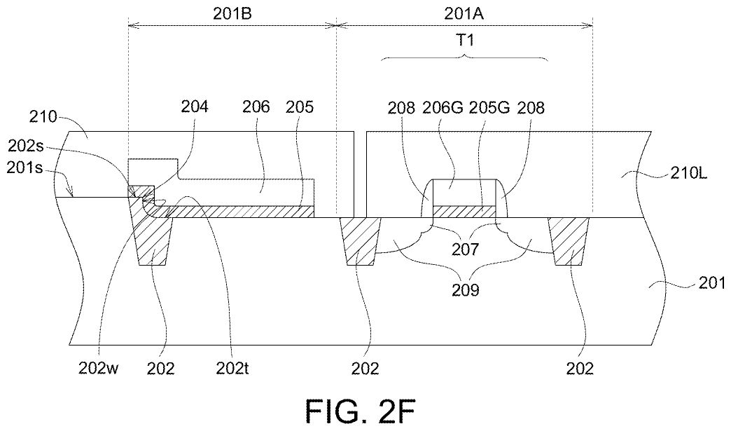

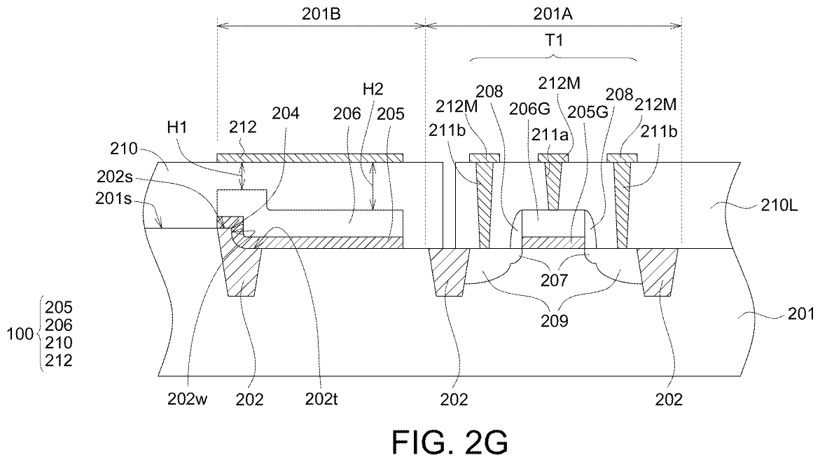

FIG. 1 is a flow chart illustrating a method for fabricating an anti-fuse structure 100 according to one embodiment of the present disclosure; and FIGS. 2A to 2G are cross-sectional views illustrating a series of the processing structures fabricating the anti-fuse structure 100 according to one embodiment of the present disclosure.

Firstly, referring to step S102: a semiconductor substrate 201 is provided, and at least one STI area 202 is formed in the semiconductor substrate 201, passing through a substrate surface 201s of the semiconductor substrate 201 and extending downward into the semiconductor substrate 201. In some embodiments of the present disclosure, the semiconductor substrate 201 may be made of a semiconductor material, such as silicon (Si), germanium (Ge), or a compound semiconductor material, such as gallium arsenide (GaAs). However, in some other embodiments, the semiconductor substrate 201 may be a silicon-on-insulator (SOI) substrate. In the present embodiment, the semiconductor substrate 201 is preferably a silicon substrate, such as a silicon wafer.

Then, the semiconductor substrate 201 is patterned by a photolithographic etching process to form at least one recess (recessed portion) 201r in the semiconductor substrate 201, extending downward from the substrate surface 201s and into the semiconductor substrate 201. Next, a dielectric material is deposited on the substrate surface 201s by a deposition process to fill each recess (recessed portion) 201r. A planarization process (for example, a chemical mechanical polishing (CMP) process) is performed to remove the portion of the dielectric material disposed above the substrate surface 201s to form a STI area 202 in each recess (recessed portion) 201r, passing through the substrate surface 201s and extending downward into the semiconductor substrate 201, thereby dividing the semiconductor substrate 201 into at least one device region 201A and one anti-fuse region 201B. In the present embodiment, the STI area 202 has an original top surface 202s that has a level substantially the same with the substrate surface 201s (as shown in FIG. 2A).

Refer to step S104: The STI area 202 disposed in the anti-fuse region 201B is etched to form a recess 202r extending downward from the original top surface 202s of the STI area 202. For example, in the present embodiment, a patterned photoresist layer 203 is formed to cover the substrate surface 201s and to expose portions of the original top surfaces 202s of the STI areas 202 disposed in the device region 201A and the anti-fuse region 201B. Then, a dry etching process is performed using a patterned photoresist layer 203 as an etching mask to remove a portion of the semiconductor substrate 201 and portions of the STI areas 202 disposed in the device region 201A and the anti-fuse region 201B. The recess 202r extending downward from the original top surface 202s of the STI areas 202 is formed in the STI 202 in the anti-fuse region 201B.

In detail, a portion of the STI 202 disposed in the anti-fuse region 201B can be removed by an etching process using the patterned photoresist layer 203 as an etching mask, to form a recess 202r extending downward from the original top surface 202s of the STI area 202. Wherein, since merely a portion of the original top surface 202s of the STI area 202 is covered by the patterned photoresist layer 203, thus the etched STI area 202 may include at least one exposed vertical sidewall 202w and an etched top surface 202t, both are together to define the recess 202r. The vertical sidewall 202w of the exposed portion of the STI area 202 not only used as a sidewall of the recess 202r, but also connected to the portion of the original top surface 202s of the STI area 202 not been etched (which covered by the patterned photoresist layer 203). In addition, a corner 204 is defined at the join portion of the sidewall of the recess 202r (the vertical sidewall 202w of the exposed portion of the STI area 202) and the un-etched portion of the original top surface 202s of the STI area 202 (as shown in FIG. 2B).

Refer to step S106: A first dielectric layer 205 is formed to cover the un-etched portion of the original top surface 202s of the STI area 202 and to cover the corner 204a formed by the vertical sidewall 202w of the exposed portion of the STI area 202 and the un-etched portion of the original top surface 202s of the STI area 202. In some embodiments of the present disclosure, the first dielectric layer 205 may be (but is not limited to) formed simultaneously with the gate oxide layer 205G disposed on the device region 201A.

For example, in the present embodiment, the formation of the first dielectric layer 205 includes steps as follows: Firstly, dielectric materials (such as, silicon oxide, silicon nitride, silicon oxynitride, high-k dielectric materials, or other suitable dielectric materials) are deposited on the substrate surface 201 and the STI area 202 (e.g., by chemical vapor deposition (CVD)), and the deposited dielectric materials are patterned to form a gate oxide layer 205G on the device region 201A, and a first dielectric layer 205 is formed above the etched portion of the STI area 202, so as to make the first dielectric layer 205 covering the corner 204 (as shown in FIG. 2C).

Refer to step S108: A poly-silicon layer 206 is formed above the dielectric layer 205 to cover the corner 204. In some embodiments of the present disclosure, the poly-silicon layer 206 may be (but is not limited to) formed simultaneously with the gate electrode layer 206G dispsoed on the device region 201A.

For example, in the present embodiment, the forming of the poly-silicon layer 206 includes steps as follows: Firstly, poly-silicon is deposited on the device region 201A and the anti-fuse region 201B (e.g., by a CVD process). The deposited poly-silicon is patterned to form a gate electrode layer 206G above the gate oxide layer 205G on the device region 201A, and at the same time, a poly-silicon layer 206 is formed above the first dielectric layer 205 on the anti-fuse region 201B, and the poly-silicon layer 206 covers the corner 204 (as shown in FIG. 2D).

Subsequently, an ion implantation process is performed to form a lightly doped drain (LDD) region 207 adjacent to the gate oxide layer 205G in the semiconductor substrate 201 of the device region 201A. Then, spacers 208 are formed on the sidewalls of the gate electrode layer 206G and the gate oxide layer 205G, and another ion implantation process is performed to form a source/drain region 209 in the semiconductor substrate 201 of the device region 201A to connect with the LDD region 207. The gate electrode layer 206G, the gate oxide layer 205G, the spacer 208, the LDD region 207 and the source/drain region 209 are combined together to form a transistor device T1 (as shown in FIG. 2E).

In another embodiment of the present disclosure, the gate electrode layer 206G made of poly-silicon and the gate oxide layer 205G can be removed to expose a portion of the substrate surface 201s in the device region 201A, and then a series of deposition and patterning processes are performed to form a seed barrier layer, a work function layer and a metal gate layer (not shown) sequentially on the exposed portion of the substrate surface 201s, together to form a metal gate structure (not shown) to replace the poly-silicon gate structure that are composed by the gate electrode layer 206G and the gate oxide layer 205G.

However, it should be appreciated that the steps performed in the device region 201A are not limited to this regards. Any processing steps used for forming semiconductor devices other than for forming the anti-fuse structure 100 do not deviate from the spirit and scope of present disclosure.

Refer to step S110: A second dielectric layer 210 is formed above the poly-silicon layer 206 to cover the corner 204. In some embodiments of the present disclosure, the second dielectric layer 210 may be formed simultaneously with the interlayer dielectric layer (ILD) 210L covering the transistor device T1.

For example, in the present embodiment, the forming of the second dielectric layer 210 includes steps as follows: Firstly, a dielectric material (such as, silicon) is deposited on the device region 201A and the anti-fuse region 201B (e.g. by a chemical vapor deposition process). to cover the poly-silicon layer 206 and the transistor element T1. After planarizing the deposited dielectric material, an etching patterning process is performed to divide the planarized dielectric material into several parts, so as to form the ILD 210L in the device region 201A, and at the same time, the second dielectric layer 210 is formed in the anti-fuse region 201B covering the poly-silicon layer 206 and the corner 204 (as shown in FIG. 2F).

Refer to step S112: A conductive layer 212 is formed above the second dielectric layer 210 to cover the corner 204. In some embodiments of the present disclosure, the conductive layer 212 may be formed simultaneously with the metal wire layer 212M that is electrically connected to the gate oxide layer 205G and the source/drain region 209 of the transistor device T1 respectively.

For example, in the present embodiment, before forming the conductive layer 212 and the metal wire layer 212M, a metal interconnection process is performed to form conductive plugs 211a and 211b in the device region 201A, passing through the ILD 210L, and respectively in contact with the gate oxide layer 205G and the source/drain region 209 of the transistor device T1. Afterwards, a metal layer is formed (for example, using a physical vapor deposition (PVD) technology) covering the ILD 210L in the device region 201A and covering the second dielectric layer 210 in the anti-fuse region 201B. The metal layer is then patterned by a photolithographic etching process to form the metal wire layer 212M on the ILD 210L and the conductive layer 212 on the anti-fuse region 201B. Wherein the metal wire layer 212M includes a plurality of metal wires electrically contacting to the conductive plugs 211a and 211b respectively, and the conductive layer 212 covers the second dielectric layer 210 and the corners 204. The poly-silicon layer 206, the second dielectric layer 210, and the conductive layer 212 that are stacked in the anti-fuse region 201B together form the anti-fuse structure 100.

Specifically, as shown in FIG. 2G, the first distance H1 between the portion of the poly-silicon layer 206 disposed at (corresponding to) the corner 204 and the conductive layer 212 is substantially smaller than the second distance H2 between the other portion of the poly-silicon layer 206 away from the corner 204 and the conductive layer 212. In other words, the resistance (or initial resistance) of the portion of the poly-silicon layer 206 disposed at (corresponding to) the corner 204 is substantially smaller than the resistance of the other portion of the poly-silicon layer 206 away from the corner 204. Whereby, the anti-fuse structure 100 is formed on a stack of the poly-silicon layer 206, the portion of the second dielectric layer 210, and the portion of the conductive layer 212 disposed at (corresponding to) the corner 204.

When a lower voltage is applied to the conductive layer 212 and the poly-silicon layer 206, no conductive path (i.e., an open circuit) can be formed between the conductive layer 212 and the poly-silicon layer 206. When a higher programming voltage (or write voltage) is applied to the conductive layer 212 and the poly-silicon layer 206, the portion of the second dielectric layer 210 disposed at (corresponding to) the corner 204 may present a thermal runaway state and may be melted to broken down due to the increase in current leakage between the conductive layer 212 and the poly-silicon layer 206. Thereby, conductive filaments will be formed between the portions of the poly-silicon layer 206 and the conductive layer 212 both disposed at (corresponding to) the corner 204, causing a short circuit between these two, and forming a permanent conduction path in the second dielectric layer 210, so as to provide an anti-fuse fault-tolerant design in the semiconductor manufacturing processes for forming an IC. At this time, the portion of the poly-silicon layer 206 (corresponding to the corner 204) has a programming resistance (e.g., the programming resistance is 0) that is much smaller than the initial resistance of the other portion of the poly-silicon layer 206 away from the corner 204. In some embodiments of the present disclosure, the programming voltage may be substantially between −3.3V and 7.5V.

According to the above embodiments of the disclosure, an anti-fuse structure and a method for fabricating the same are provided using existing reticles and processing steps used for manufacturing other semiconductor devices in the semiconductor manufacturing process. Firstly, an etching process is performed to form a recess concaved from the top surface of a STI area, and then a first dielectric layer, a poly-silicon layer, a second dielectric layer (for example, an ILD) and a conductive layer (such as, a metal wire layer) are formed in series to cover the corner that is formed by a vertical sidewall of the recess and the top surface of the STI area. Such that, a first distance between the portion of the poly-silicon layer corresponding to the corner and the conductive layer is lower than a second distance between the other portion of the poly-silicon layer away from the corner and the conductive layer. Thereby, an anti-fuse structure can be formed above the corner to provide an anti-fuse fault-tolerant design during the process for forming an IC, without (or not significantly) increasing the number of reticles and process steps.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An anti-fuse structure, comprising:
a substrate having a substrate surface;
a shallow trench isolation (STI) area, passing through the substrate surface and extending downward into the substrate, wherein the STI area has a top surface and recess extending downward from the top surface;
a first dielectric layer, disposed above the STI area and covering the top surface and a corner that is formed by a vertical sidewall of the recess and the top surface;
a poly-silicon layer, disposed above the first dielectric layer and covering the corner;
a second dielectric layer, disposed above the poly-silicon layer and covering the corner; and
a conductive layer, disposed above the second dielectric layer and covering the corner.

2. The anti-fuse structure according to claim 1, wherein a first distance between a portion of the poly-silicon layer corresponding to the corner and the conductive layer is lower than a second distance between another portion of the poly-silicon layer away from the corner and the conductive layer.

3. The anti-fuse structure according to claim 2, wherein the portion of the poly-silicon layer corresponding to the corner has an initial resistance; after applying a programming voltage to the conductive layer, the portion of the poly-silicon layer corresponding to the corner has a programming resistance, and the programming resistance is substantially less than the initial resistance.

4. The anti-fuse structure according to claim 3, wherein the programming voltage substantially ranges between-3.3V and 7.5V.

5. The anti-fuse structure according to claim 1, wherein the first dielectric layer is a gate dielectric layer; the poly-silicon layer is a gate electrode layer; the second dielectric layer is an interlayer dielectric layer (ILD); and the conductive layer is a metal wire layer.

6. A method for fabricating an anti-fuse structure, comprising:
providing a substrate;
forming at least one STI area in the substrate, passing through a surface of the substrate and extending downward into the substrate;
etching the STI area to form a recess extending downward from a top surface of the STI area;
forming a first dielectric layer above the STI area to cover the top surface and a corner that is formed by a vertical sidewall of the recess and the top surface;
forming a poly-silicon layer above the first dielectric layer to cover the corner;
forming a second dielectric layer above the poly-silicon layer to cover the corner; and
forming a conductive layer above the second dielectric layer to cover the corner.
